(19) United States
(12) Patent Application Publication
(10) Pub. No.: US 2021/0159025 A1
(43) Pub. Date: May 27, 2021

(54) METHOD FOR CALCULATING THE CONTACT STATE OF AN ELECTRICAL SWITCH, AND ELECTRICAL SWITCH WITH SUCH A METHOD

(71) Applicant: Siemens Aktiengesellschaft, Muenchen (DE)

(72) Inventors: Thomas MOOSBURGER, Regensburg (DE); Thomas BECKERT, Nuernberg (DE); Stefan WIDMANN, Freudenberg, OT Lintach (DE)

(73) Assignee: Siemens Aktiengesellschaft, Muenchen (DE)

(21) Appl. No.: 17/058,864

(22) PCT Filed: May 14, 2019
(86) PCT No.: PCT/EP2019/062287

§ 371 Date: Nov. 25, 2020

(30) Foreign Application Priority Data
May 30, 2018 (DE) 10 2018 208 577.3

(51) Int. Cl. H01H 1/00; G01R 31/327

(52) U.S. Cl. CPC H01H 1/0015; G01R 31/3277

(57) ABSTRACT

A method for calculating the contact state of an electrical switch is disclosed, In an embodiment, the method includes: collecting first input values for calculating the contact state in a first component of the electrical switch; collecting second input values for calculating the contact state in a second component of the electrical switch; and calculating the contact state of the electrical switch from the first input values and the second input values.

### PRIORITY STATEMENT

This application is the national phase under 35 U.S.C. § 371 of PCT International Application No. PCT/EP2019/062287, which has an International filing date of May 14, 2019, which designated the United States of America and which claims priority to German application DE 102018208577.3 filed May 30, 2018, the entire contents of each of which are hereby incorporated herein by reference.

### FIELD

Embodiments of invention relate invention relates to a method for calculating the contact state of an electrical switch and to an electrical switch with such a method.

### BACKGROUND

In order to visualize and establish the maintenance requirement of contact systems, for example in compact circuit breakers, it is necessary to ascertain the physical state of the contacts. Contacts typically wear during connection and disconnection processes, specifically during the tripping of compact circuit breakers.

Various methods for determining the contact state of contact systems are known. In the case of ACB (air circuit breaker) switches, for example, mechanical systems are known that, in the form of a plunger, determine the thickness of the remaining contact material optically.

Software-based contact state assessments are also known that, for example in the form of the summation of square values of the current in the event of tripping, draw conclusions about the contact state.

Furthermore, systems are known that assess the contact state during disconnection processes and tripping operations within the electronic trip unit (ETU). This function is active only for an extraneous supply and operative only during disconnection processes. The state of the contact with maximum wear is displayed on a remote display. To detect a disconnection process not caused by tripping, that is to say not caused by the ETU itself, the system uses a dedicated signal line between the communication accessories and the ETU. The communication accessories in this instance have the function of examining the switch state on the basis of two contacts. This system requires two additional devices for the complete functionality of the contact state assessment.

### SUMMARY

At least one embodiment of the invention provides an alternative method for determining the contact state of an electrical switch that overcomes the disadvantages known in the prior art.

Embodiments according to the invention are directed to a method for calculating the contact state of an electrical switch. Advantageous configurations of the method according to the invention are specified in the claims. Embodiments according to the invention are also directed to an electrical switch and system.

The method for calculating the contact state of an electrical switch according to an embodiment comprises:

collecting first input values for calculating the contact state in a first component of the electrical switch;

collecting second input values for calculating the contact state in a second component of the electrical switch; and

calculating the contact state of the electrical switch from the first input values and the second input values.

The electrical switch according to an embodiment of the invention comprises a first component and a second component, wherein the contact state is calculated using a method according to an embodiment of the invention.

The system according to the invention according to an embodiment comprises an electrical switch according to an embodiment of the invention and a third component for calculating the contact state from the first input values and the second input values.

### BRIEF DESCRIPTION OF THE DRAWINGS

The properties, features and advantages of this invention that are described above and the way in which they are achieved will become clearer and more distinctly comprehensible in conjunction with the description of the exemplary embodiments that follows, the exemplary embodiments being explained in more detail in conjunction with the figures, in which:

FIG. 1 shows the system design for assessing the contact state;

FIG. 2 shows the method according to an embodiment of the invention for calculating the contact state of the electrical switch;

FIG. 3 shows an alternative embodiment of the method according to the invention for calculating the contact state;

FIG. 4 shows a further alternative embodiment of the method for calculating the contact state; and

FIG. 5 shows the method according to an embodiment of the invention for calculating the contact state in a third component.

### DETAILED DESCRIPTION OF THE EXAMPLE EMBODIMENTS

The method for calculating the contact state of an electrical switch according to an embodiment comprises:

collecting first input values for calculating the contact state in a first component of the electrical switch;

collecting second input values for calculating the contact state in a second component of the electrical switch; and

calculating the contact state of the electrical switch from the first input values and the second input values.

The method according to an embodiment of the invention for calculating the contact state has the following advantages over known solutions. Connection and disconnection processes can be considered and included in the assessment of the states of the respective contacts. Moreover, no additional device is necessary, which means that an accessory pocket remains vacant in the compact circuit breaker for other accessories. Furthermore, an advantage of the method according to an embodiment of the invention is that no dedicated signal line is necessary between accessories and the ETU in order to transmit the switch state to the ETU.

In one configuration of the method according to an embodiment of the invention, the method comprises the further step of:

transmitting the first input values from the first component to the second component of the electrical switch; wherein the contact state of the electrical switch is calculated from the first input values and the second input values in the second component.

In one alternative configuration, the method according to an embodiment of the invention comprises the further step of:

transmitting the second input values from the second component to the first component of the electrical switch; wherein the contact state of the electrical switch is calculated from the first input values in the first component.

In one alternative configuration of the method according to an embodiment of the invention, the method comprises the further step of:

transmitting the first input values and the second input values from the first and second components to a third component of the electrical switch; wherein the contact state of the electrical switch is calculated from the first input values and the second input values in the third component.

In one further configuration of the method according to an embodiment of the invention, the collecting of first input values means that the breaker status sensor (BSS) signal and/or the trip alarm switch (TAS) signal are measured and/or evaluated.

In one further configuration of the method according to an embodiment of the invention, the collecting of second input values means that the current when the electrical switch disconnects, the rated current and/or the current when the electrical switch connects are measured and/or evaluated.

In one configuration of the method according to the invention, the first component is a communication module and the second component is an electronic trip unit (ETU).

In one further configuration of the method according to an embodiment of the invention, the third component is a data concentrator module arranged outside the electrical switch.

The electrical switch according to an embodiment of the invention comprises a first component and a second component, wherein the contact state is calculated using a method according to an embodiment of the invention.

The system according to the invention according to an embodiment comprises an electrical switch according to an embodiment of the invention and a third component for calculating the contact state from the first input values and the second input values.

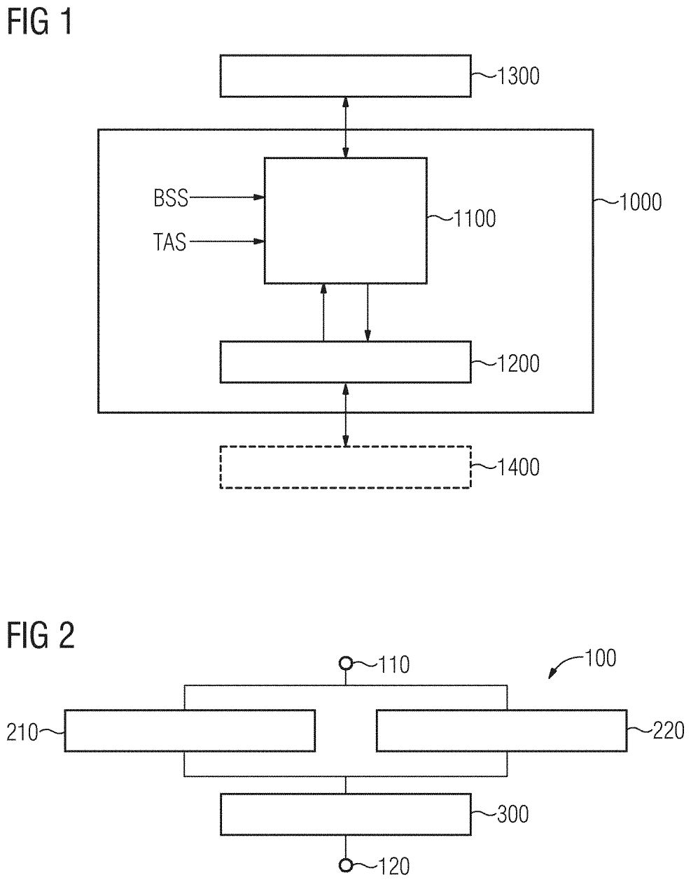

FIG. 1 depicts the fundamental system design for assessing the contact state of an electrical switch 1000. In this regard, the electrical switch 1000 comprises a first component 1100 and a second component 1200. The first component 1100 and the second component 1200 can each interchange data with one another. By way of example, the interchange of the data between the first component 1100 and the second component 1200 can take place via a wired connection or similarly via a radio connection.

The first component 1100 may be for example a communication module that makes various states and measured values of the electrical switch 1000 available externally. In this regard, there may exist a communication connection to a third component 1300 that is arranged outside the electrical switch 1000 and for example is connected to multiple electrical switches 1000. This third component 1300 may be for example a data concentrator module that communicates with various electrical switches 1000.

The second component 1200 of the electrical switch 1000 may be an electronic trip unit (ETU), for example. The task of such an electronic trip unit (ETU) is to constantly monitor the current of the electrical switch 1000 in order to detect electrical states of the switch 1000 and to take countermeasures if necessary.

K0121 The first component 1100 continually collects 210 first input values, for example the breaker status sensor (BSS) signal and/or the trip alarm switch (TAS) signal. Similarly, the second component 1200 constantly collects 220 second input values, for example the current when the electrical switch 1000 disconnects, the rated current and/or the current when the electrical switch 1000 connects.

FIG. 2 depicts the method 100 according to an embodiment of the invention for calculating the contact state of an electrical switch 1000. The method 100 starts at 110 and ends at 120. The method 100 according to an embodiment of the invention comprises the steps of:

collecting first input values 210 for calculating the contact state in a first component 1100 of the electrical switch 1000;

collecting second input values 220 for calculating the contact state in a second component 1200 of the electrical switch 1000; and

calculating 300 the contact state of the electrical switch 1000 from the first input values and the second input values.

As described above, the collecting of first input values 210 and the collecting of second input values 220 can take place in parallel, which means that these first and second input values are used for calculating 300 the contact state of the electrical switch 1000. First input values for calculating 300 the contact state are for example the breaker status sensor (BSS) and/or trip alarm switch (TAS) signal. The second input values for calculating 300 the contact state are for example the current when the electrical switch 1000 disconnects, the rated current of the electrical switch 1000 and/or the current when the electrical switch 1000 connects.

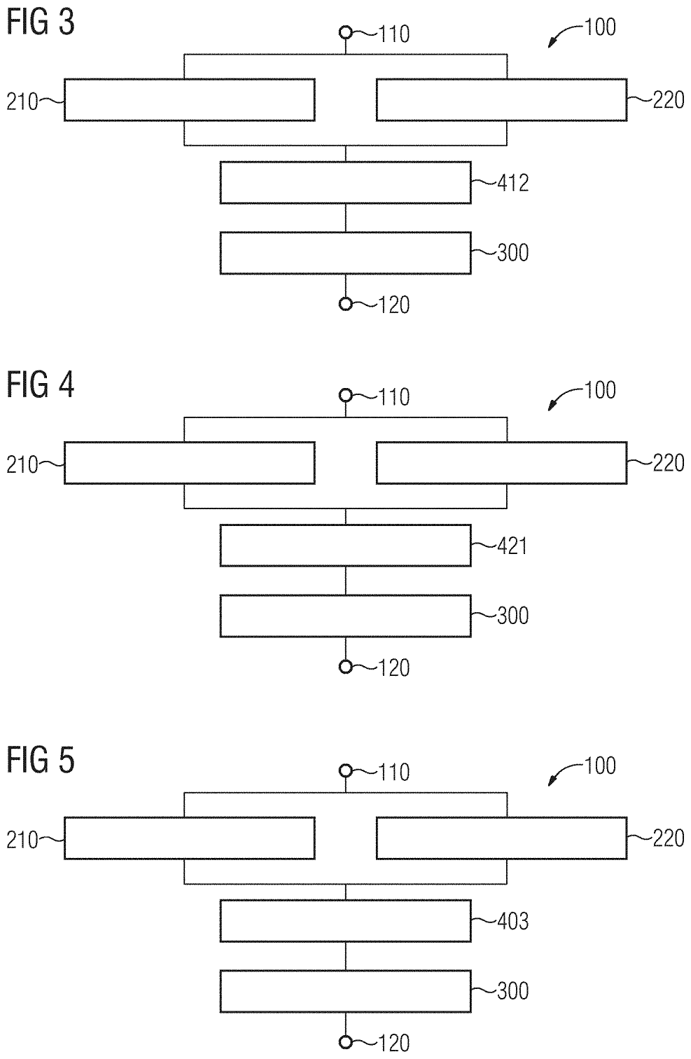

FIG. 3 depicts a further embodiment of the method 100 according to the invention for calculating the contact state of an electrical switch 1000. This method 100 comprises the further step of:

transmitting the first input values 412 from the first component 1100 to the second component 1200 of the electrical switch 1000; wherein the contact state of the electrical switch 1000 is calculated from the first input values and the second input values in the second component 1200.

If the second component 1200 is an electronic trip unit (ETU) then the result of the calculation 300 of the contact state can for example in turn be transmitted via the first component 1100 as communication module to the third component 1300 as data concentrator module and for example be displayed on a central computer installation.

The contact state can typically be represented as a state of health of the electrical contacts of from 100% to 0%; a traffic light representation in the colors red, amber and green is likewise conceivable. The third component 1300 as data concentrator module or a component mounted on top can for example use a radio connection to forward the contact state of the electrical switch 1000 to mobile display and input devices such as smartphones or tablet computers.

FIG. 4 shows an alternative method 100 for calculating the contact state of an electrical switch 1000 having the further step of:

transmitting the second input values 421 from the second component 1200 to the first component 1100 of the electrical switch 1000; wherein the contact state of the electrical switch 1000 is calculated from the first input values and the second input values in the first component 1100.

This alternative method 100 for calculating the contact state involves the calculating 300 of the contact state being performed in the first component 1100, for example in the communication module. In this case too the result of the calculation of the contact state can be forwarded to the third component 1300 as data concentrator module and accordingly conditioned for and made available to a user.

FIG. 5 depicts a further method 100 according to an embodiment of the invention for calculating the contact state of an electrical switch 1000 having the further step of:

transmitting the first input values and the second input values 403 from the first and second components 1100; 1200 to a third component 1300 of the electrical switch; wherein the contact state of the electrical switch 1000 is calculated from the first input values and the second input values in the third component 1300.

If the third component 1300 is a data concentrator module then the first component 1100 as communication module and the second component 1200 as electronic trip unit (ETU) send their first input values and second input values to the third component 1300; the calculation 300 of the contact state is performed by the third component 1300.

In accordance with the depiction in FIG. 1 there may be provision for the second component 1200, for example as electronic trip unit (ETU), to be able to communicate with a fourth component 1400, which is likewise arranged outside the electrical switch 1000. This fourth component 1400 may be for example a test device that is briefly connected to the second component 1200 when the electrical switch 1000 or the installation is started up. This fourth component 1400 can graphically reproduce the calculated contact state.

The first component 1100 as communication module has information available about the present state of the electrical switch 1000 as a result of examining the breaker status sensor (BSS) and trip alarm switch (TAS) signals. In one embodiment this information can be provided to the second component 1200 as electronic trip unit (ETU) via a communication connection. The communication connection used may be an I2C bus, for example; other bus connections, wired or as a radio system, can be used for the communication connection between the first component 1100 and the second component 1200.

The second component 1200 assesses the current that has flowed via the contacts to date in the event of a connection or disconnection process or a tripping of the electrical switch 1000 and uses a removal function to calculate the associated expected removal of contact material for the respective contact for the level of current. Depending on the electrical switch 1000 it is possible for multiple contacts to be assessed in this regard. While tripping processes are initiated by the second component 1200 as electronic trip unit (ETU) itself, the ETU learns of the respective switching process in the event of connection and disconnection processes via the communication connection between the first component 1100 and the second component 1200. As a result, the ETU can initiate an applicable assessment of the current that has flowed to date and the effects of the current on the respective contacts.

1. A method for calculating a contact state of an electrical switch, the method comprising:
collecting first input values for calculating the contact state in a first component of the electrical switch;
collecting second input values for calculating the contact state in a second component of the electrical switch; and
calculating the contact state of the electrical switch from the first input values and the second input values.

2. The method of claim 1, further comprising:
transmitting the first input values from the first component to the second component of the electrical switch;
wherein the contact state of the electrical switch is calculated from the first input values and the second input values in the second component.

3. The method of claim 1, further comprising:
transmitting the second input values from the second component to the first component of the electrical switch;
wherein the contact state of the electrical switch is calculated from the first input values and the second input values in the first component.

4. The method of claim 1, further comprising:
transmitting the first input values and the second input values from the first and second components to a third component of the electrical switch;
wherein the contact state of the electrical switch is calculated from the first input values and the second input values in the third component.

5. The method of claim 1, wherein the collecting of first input values means that at least one of a breaker status sensor signal and a trip alarm switch signal are at least one of measured and evaluated.

6. The method of claim 1, wherein the collecting of second input values means that at least one of a current when the electrical switch disconnects, a rated current and a current when the electrical switch connects are at least one of measured and evaluated.

7. The method of claim 1, wherein the first component is a communication module and the second component is an electronic trip unit.

8. The method of claim 4, wherein the third component is a data concentrator module arranged outside the electrical switch.

9. An electrical switch, comprising:
a first component; and
a second component, wherein the contact state is calculated using the method of claim 1.

10. A system, comprising:
the electrical switch of claim 9; and
a third component to calculate the contact state of the electrical switch from the first input values and the second input values.

11. The method of claim 2, wherein the collecting of first input values means that at least one of a breaker status sensor signal and a trip alarm switch signal are at least one of measured and evaluated.

12. The method of claim 2, wherein the collecting of second input values means that at least one of a current when the electrical switch disconnects, a rated current and a current when the electrical switch connects are at least one of measured and evaluated.

13. The method of claim 3, wherein the collecting of first input values means that at least one of a breaker status sensor signal and a trip alarm switch signal are at least one of measured and evaluated.

14. The method of claim 3, wherein the collecting of second input values means that at least one of a current when the electrical switch disconnects, a rated current and a current when the electrical switch connects are at least one of measured and evaluated.

15. The method of claim 4, wherein the collecting of first input values means that at least one of a breaker status sensor signal and a trip alarm switch signal are at least one of measured and evaluated.

16. The method of claim 4, wherein the collecting of second input values means that at least one of a current when the electrical switch disconnects, a rated current and a current when the electrical switch connects are at least one of measured and evaluated.

17. A system, comprising:
an electrical switch, including a first component and a second component; and
a third component to calculate a contact state of the electrical switch by at least:
collecting first input values for calculating the contact state in a first component of the electrical switch,
collecting second input values for calculating the contact state in a second component of the electrical switch, and
calculating the contact state of the electrical switch from the first input values and the second input values.

18. The system of claim 17, wherein the third component is configured to calculate the contact state of the electrical switch by further,
transmitting the first input values from the first component to the second component of the electrical switch;
wherein the contact state of the electrical switch is calculated from the first input values and the second input values in the second component.

19. The system of claim 17, wherein the third component is configured to calculate the contact state of the electrical switch by further,
transmitting the second input values from the second component to the first component of the electrical switch;
wherein the contact state of the electrical switch is calculated from the first input values and the second input values in the first component.

20. The system of claim 17, wherein the third component is configured to calculate the contact state of the electrical switch by further,
transmitting the first input values and the second input values from the first and second components to a third component of the electrical switch (1000);
wherein the contact state of the electrical switch is calculated from the first input values and the second input values in the third component.
